(19) United States
(12) Patent Application Publication
(10) Pub. No.: US 2022/0336025 A1
(43) Pub. Date: Oct. 20, 2022

(54) SEMICONDUCTOR MEMORY DEVICE AND METHOD OF OPERATING THE SAME

(71) Applicant: SK hynix Inc., Icheon-si Gyeonggi-do (KR)

(72) Inventors: Hee Youl LEE, Icheon-si Gyeonggi-do (KR); Kwang Min LIM, Icheon-si Gyeonggi-do (KR)

(73) Assignee: SK hynix Inc., Icheon-si Gyeonggi-do (KR)

(21) Appl. No.: 17/495,476

(22) Filed: Oct. 6, 2021

(30) Foreign Application Priority Data
Apr. 15, 2021 (KR) 10-2021-0049205

(51) Int. Cl. G11C 16/34; G11C 16/04; G11C 16/08; G11C 16/10; G11C 16/24

(52) U.S. Cl. CPC G11C 16/3427; G11C 16/0483; G11C 16/08; G11C 16/10; G11C 16/24

(57) ABSTRACT

Selected memory cells are programmed by a method of operating a semiconductor memory device. The method includes setting a state of bit lines connected to a selected memory block including the selected memory cells; applying a turn-on voltage to a drain select line connected to the selected memory block, and applying a turn-off voltage to a source select line connected to the memory block; starting to increase a voltage of word lines of a first group of word lines including unselected word lines which are not connected to the selected memory cells and a selected word line connected to the selected memory cells, among a plurality of word lines connected to the selected memory block; and starting to increase a voltage of word lines of a second group of word lines, not included in the first group of word lines, including unselected word lines connected to the selected memory block.

### CROSS-REFERENCE TO RELATED APPLICATION

The present application claims priority under 35 U.S.C. § 119(a) to Korean patent application number 10-2021-0049205 filed on Apr. 15, 2021, in the Korean Intellectual Property Office, the entire disclosure of which is incorporated by reference herein.

### BACKGROUND

### 1. Technical Field

The present application relates to an electronic device, and more particularly, to a semiconductor memory device and a method of operating the same.

### 2. Related Art

A semiconductor memory device may be formed in a two-dimensional structure in which strings are horizontally arranged on a semiconductor substrate, or in a three-dimensional structure in which the strings are vertically stacked on the semiconductor substrate. A three-dimensional memory device is a memory device designed to resolve a limit of an integration degree of a two-dimensional memory device, and may include a plurality of memory cells that are vertically stacked on a semiconductor substrate.

### SUMMARY

An embodiment of the present disclosure is directed to a semiconductor memory device having an improved program characteristic and a method of operating the same.

Selected memory cells among a plurality of memory cells may be programmed by a method of operating a semiconductor memory device. The method of operating the semiconductor memory device includes setting a state of bit lines connected to a selected memory block including the selected memory cells; applying a turn-on voltage to a drain select line connected to the selected memory block, and applying a turn-off voltage to a source select line connected to the memory block; starting to increase a voltage of word lines of a first group of word lines including unselected word lines which are not connected to the selected memory cells and a selected word line connected to the selected memory cells, among a plurality of word lines connected to the selected memory block; and starting to increase a voltage of word lines of a second group of word lines including unselected word lines connected to the selected memory block which are not in the first group of word lines.

In an embodiment, the first group may include unselected word lines positioned between the drain select line and the selected word line.

In an embodiment, the second group may include unselected word lines positioned between the source select line and the selected word line.

In an embodiment, the first group may include unselected word lines which are not positioned adjacent to the selected word line.

In an embodiment, the second group may include unselected word lines positioned adjacent to the selected word line.

In an embodiment, starting to increase the voltage of the word lines of the first group includes starting to increase the voltage of the unselected word lines of the first group from a ground voltage to a pass voltage and starting to increase the voltage of the selected word line of the first group from the ground voltage to a program voltage.

In an embodiment, starting to increase the voltage of the word lines of the second group includes starting to increase the voltage of the word lines of the second group from the ground voltage to the pass voltage.

In an embodiment, starting to increase the voltage of the word lines of the first group includes starting to increase the voltage of the unselected word lines of the first group and the voltage of the selected word line of the first group from a ground voltage to a pass voltage.

In an embodiment, the method may further include increasing the voltage of the selected word line from the pass voltage to the program voltage, after the voltage of the selected word line is increased to the pass voltage.

In an embodiment, setting the state of the bit lines may include applying a program permission voltage to a selected bit line among the bit lines and applying a program inhibition voltage greater than the program permission voltage to an unselected bit line.

In an embodiment, the program permission voltage may be a ground voltage.

In an embodiment, setting the state of the bit line may include applying a program permission voltage to a selected bit line among the bit lines and floating an unselected bit line.

A semiconductor memory device according to another embodiment of the present disclosure includes a plurality of memory blocks, a peripheral circuit, and control logic. Each of the plurality of memory blocks includes a plurality of memory cells. The peripheral circuit is configured to perform a program operation on selected memory cells of a selected memory block among the plurality of memory blocks. The control logic is capable of controlling the program operation performed by the peripheral circuit. Each of the plurality of memory blocks is connected to at least one drain select line, at least one source select line, and a plurality of word lines. The control logic is capable of: controlling the peripheral circuit to apply a turn-on voltage to at least one drain select line connected to the selected memory block and apply a turn-off voltage to at least one source select line connected to the memory block; controlling the peripheral circuit to increase a voltage of unselected word lines included in a first group which are not connected to the selected memory cells and a selected word line included in the first group which is connected to the selected memory cells, among a plurality of word lines connected to the selected memory block; and controlling the peripheral circuit to increase, after the voltage of the unselected word lines of the first group and the selected word line are started to be increased, a voltage of word lines included in a second group of word lines including unselected word lines connected to the selected memory block which are not in the first group of word lines.

In an embodiment, the first group may include unselected word lines positioned between the at least one drain select line and the selected word line.

In an embodiment, the second group may include unselected word lines positioned between the at least one source select line and the selected word line.

In an embodiment, the first group may include unselected word lines which are not positioned adjacent to the selected word line.

In an embodiment, the second group may include unselected word lines positioned adjacent to the selected word line.

In an embodiment, the control logic is capable of controlling the peripheral circuit to: increase the voltage of the unselected word lines of the first group from a ground voltage to a pass voltage; and increase the voltage of the selected word line of the first group from the ground voltage to a program voltage.

In an embodiment, the control logic is capable of controlling the peripheral circuit to increase the voltage of the word lines of the second group from the ground voltage to the pass voltage.

In an embodiment, the control logic is capable of controlling the peripheral circuit to: increase the voltage of the unselected word lines of the first group and the selected word line of the first group from a ground voltage to a pass voltage; and further increase the voltage of the selected word line from the pass voltage to the program voltage.

Some embodiments of the present disclosure are directed to a semiconductor memory device having an improved program characteristic and a method of operating the same.

### BRIEF DESCRIPTION OF THE DRAWINGS

FIG. 1 is a block diagram illustrating a semiconductor memory device according to an embodiment of the present disclosure.

FIG. 2 is a block diagram illustrating an embodiment of a memory cell array of FIG. 1.

FIG. 3 is a circuit diagram illustrating any one memory block of memory blocks of FIG. 2.

FIG. 4 is a circuit diagram illustrating another embodiment of any one memory block of the memory blocks of FIG. 2.

FIG. 5 is a circuit diagram illustrating an embodiment of any one memory block of the memory blocks included in the memory cell array of FIG. 1.

FIG. 6 is a diagram illustrating a plurality of program loops included in a program operation of a semiconductor memory device.

FIG. 7 is a circuit diagram illustrating a program operation of a selected memory block.

FIG. 8 is a timing diagram illustrating an embodiment of a program pulse application step shown in FIG. 6.

FIG. 9 is a diagram illustrating an injection phenomenon occurring during the program operation according to FIG. 8.

FIG. 10 is a flowchart illustrating a method of operating a semiconductor memory device according to an embodiment of the present disclosure.

FIG. 11 is a timing diagram illustrating the program pulse application step of FIG. 6 according to an embodiment of the present disclosure.

FIG. 12 is a circuit diagram illustrating an embodiment of unselected word lines included in a first group and a second group.

FIG. 13 is a flowchart illustrating a method of operating a semiconductor memory device according to an example of FIG. 12.

FIG. 14 is a circuit diagram illustrating another embodiment of the unselected word lines included in the first group and the second group.

FIG. 15 is a flowchart illustrating a method of operating a semiconductor memory device according to an example of FIG. 14.

FIG. 16 is a block diagram illustrating a memory system including the semiconductor memory device of FIG. 1.

FIG. 17 is a block diagram illustrating an application example of the memory system of FIG. 16.

FIG. 18 is a block diagram illustrating a computing system including the memory system described with reference to FIG. 17.

### DETAILED DESCRIPTION

Specific structural or functional descriptions are disclosed to describe embodiments according to the concept of the present disclosure. Embodiments according to the concept of the present disclosure may be carried out in various forms and should not be construed as being limited to the particular embodiments described in the present specification or application.

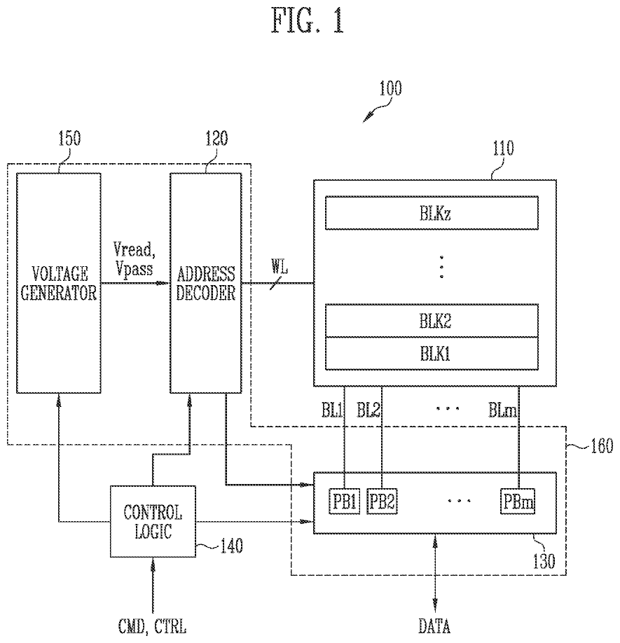

FIG. 1 is a block diagram illustrating a semiconductor memory device 100 according to an embodiment of the present disclosure.

Referring to FIG. 1, the semiconductor memory device 100 includes a memory cell array 110, an address decoder 120, a read and write circuit 130, control logic 140, and a voltage generator 150.

The memory cell array 110 includes a plurality of memory blocks BLK1 to BLKz. The plurality of memory blocks BLK1 to BLKz are connected to the address decoder 120 through word lines WL. The plurality of memory blocks BLK1 to BLKz are connected to the read and write circuit 130 through bit lines BL1 to BLm. Each of the plurality of memory blocks BLK1 to BLKz includes a plurality of memory cells. As an embodiment, the plurality of memory cells are non-volatile memory cells, and may be configured of non-volatile memory cells having a vertical channel structure. The memory cell array 110 may be configured as a memory cell array of a two-dimensional structure. According to an embodiment, the memory cell array 110 may be configured as a memory cell array of a three-dimensional structure. Meanwhile, each of the plurality of memory cells included in the memory cell array may store at least one bit of data. In an embodiment, each of the plurality of memory cells included in the memory cell array 110 may be a single-level cell (SLC) storing one bit of data. In another embodiment, each of the plurality of memory cells included in the memory cell array 110 may be a multi-level cell (MLC) storing two bits of data. In still another embodiment, each of the plurality of memory cells included in the memory cell array 110 may be a triple-level cell storing three bits of data. In still another embodiment, each of the plurality of memory cells included in the memory cell array 110 may be a quad-level cell storing four bits of data. According to an embodiment, the memory cell array 110 may include a plurality of memory cells each storing five or more bits of data.

The address decoder 120, the read and write circuit 130, and the voltage generator 150 operate as a peripheral circuit 160 that drives the memory cell array 110. At this time, the peripheral circuit 160 is operated under the control of the control logic 140. The address decoder 120 is connected to the memory cell array 110 through the word lines WL. The address decoder 120 is configured to operate in response to control of the control logic 140. The address decoder 120 receives an address through an input/output buffer (not shown) inside the semiconductor memory device 100.

The address decoder 120 is configured to decode a block address among received addresses. The address decoder 120 selects at least one memory block according to the decoded block address. In addition, the address decoder 120 applies a read voltage Vread generated in the voltage generator 150 to a selected word line of the selected memory block at a time of a read voltage application operation during a read operation, and applies a pass voltage Vpass to the remaining unselected word lines. In addition, during a program verify operation, the address decoder 120 applies a verify voltage generated in the voltage generator 150 to the selected word line of the selected memory block, and applies the pass voltage Vpass to the remaining unselected word lines.

The address decoder 120 is configured to decode a column address of the received addresses. The address decoder 120 transmits the decoded column address to the read and write circuit 130.

A read operation and a program operation of the semiconductor memory device 100 are performed in a page unit. Addresses received at a time of a request of the read operation and the program operation include a block address, a row address, and a column address. The address decoder 120 selects one memory block and one word line according to the block address and the row address. The column address is decoded by the address decoder 120 and is provided to the read and write circuit 130.

The address decoder 120 may include a block decoder, a row decoder, a column decoder, an address buffer, and the like.

The read and write circuit 130 includes a plurality of page buffers PB1 to PBm. The read and write circuit 130 may operate as a “read circuit” during a read operation of the memory cell array 110 and may operate as a “write circuit” during a write operation of the memory cell array 110. The plurality of page buffers PB1 to PBm are connected to the memory cell array 110 through the bit lines BL1 to BLm. During the read operation and the program verify operation, in order to sense a threshold voltage of the memory cells, the plurality of page buffers PB1 to PBm sense a change of an amount of a current flowing according to a program state of a corresponding memory cell through a sensing node while continuously supplying a sensing current to the bit lines connected to the memory cells, and latches the sensed change as sensing data. The read and write circuit 130 operates in response to page buffer control signals output from the control logic 140.

During the read operation, the read and write circuit 130 senses data of the memory cell, temporarily stores read data, and outputs data DATA to the input/output buffer (not shown) of the semiconductor memory device 100. As an embodiment, the read and write circuit 130 may include a column selection circuit, and the like, in addition to the page buffers (or page registers).

The control logic 140 is connected to the address decoder 120, the read and write circuit 130, and the voltage generator 150. The control logic 140 receives a command CMD and a control signal CTRL through the input/output buffer (not shown) of the semiconductor memory device 100. The control logic 140 is configured to control overall operations of the semiconductor memory device 100 in response to the control signal CTRL. In addition, the control logic 140 outputs a control signal for adjusting a sensing node precharge potential level of the plurality of page buffers PB1 to PBm. The control logic 140 may control the read and write circuit 130 to perform the read operation of the memory cell array 110. The control logic controls the voltage generator 150 to generate various voltages used during the program operation of the memory cell array 110. In addition, the control logic 140 controls the address decoder 120 to transfer the voltages generated by the voltage generator 150 to local lines of a memory block which is an operation target through global lines. Meanwhile, the control logic 140 controls the read and write circuit 130 to read data of a selected page of the memory block through the bit lines BL1 to BLm during the read operation and store the data in the page buffers PB1 to PBm. In addition, the control logic 140 controls the read and write circuit 130 to program the data, which is stored in the page buffers PB1 to PBm, in the selected page during the program operation. The control logic 140 may be implemented as hardware, software, or a combination of hardware and software. For example, the control logic 140 may be a control logic circuit operating in accordance with an algorithm and/or a processor executing control logic code.

The voltage generator 150 generates the read voltage Vread and the pass voltage Vpass during the read operation in response to the control signal output from the control logic 140. In order to generate a plurality of voltages having various voltage levels, the voltage generator 150 may include a plurality of pumping capacitors that receive an internal power voltage, and generate the plurality of voltages by selectively activating the plurality of pumping capacitors in response to the control of the control logic 140.

The address decoder 120, the read and write circuit 130, and the voltage generator 150 may function as a “peripheral circuit 160” that performs a read operation, a write operation, and an erase operation on the memory cell array 110. The peripheral circuit 160 performs the read operation, the write operation, and the erase operation on the memory cell array 110 based on the control of the control logic 140.

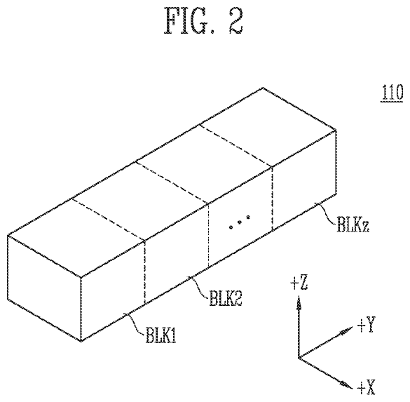

FIG. 2 is a block diagram illustrating an embodiment of the memory cell array 110 of FIG. 1.

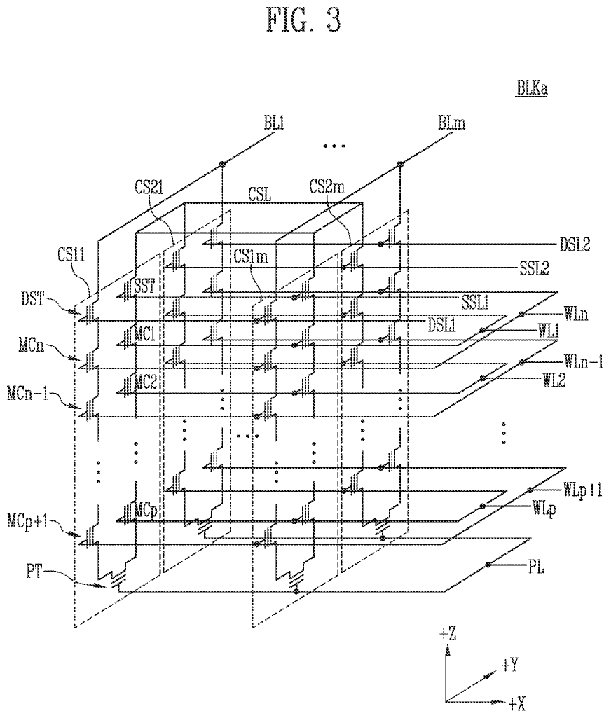

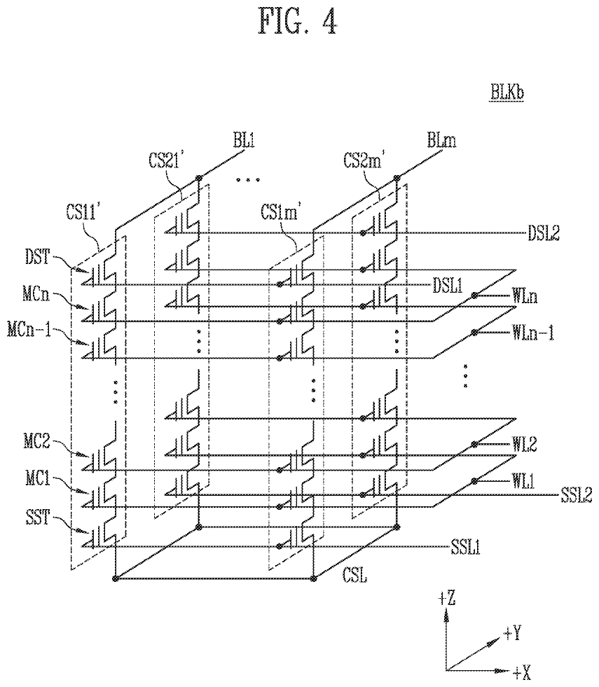

Referring to FIG. 2, the memory cell array 110 includes a plurality of memory blocks BLK1 to BLKz. Each memory block has a three-dimensional structure. Each memory block includes a plurality of memory cells stacked on a substrate. Such plurality of memory cells are arranged along a +X direction, a +Y direction, and a +Z direction. A structure of each memory block is described in more detail with reference to FIGS. 3 and 4.

FIG. 3 is a circuit diagram illustrating any one memory block BLKa of the memory blocks BLK1 to BLKz of FIG. 2.

Referring to FIG. 3, the memory block BLKa includes a plurality of cell strings CS11 to CS1m and CS21 to CS2m. As an embodiment, each of the plurality of cell strings CS11 to CS1m and CS21 to CS2m may be formed in a ‘U’ shape. In the memory block BLKa, m cell strings are arranged in a row direction (that is, the +X direction). In FIG. 3, two cell strings are arranged in a column direction (that is, the +Y direction). However, this is for convenience of description, and three or more cell strings may be arranged in the column direction.

Each of the plurality of cell strings CS11 to CS1m and CS21 to CS2m includes at least one source select transistor SST, first to n-th memory cells MC1 to MCn, a pipe transistor PT, and at least one drain select transistor DST.

Each of the select transistors SST and DST and the memory cells MC1 to MCn may have a similar structure. As an embodiment, each of the select transistors SST and DST and the memory cells MC1 to MCn may include a channel layer, a tunneling insulating film, a charge storage film, and a blocking insulating film. As an embodiment, a pillar for providing the channel layer may be provided in each cell string. As an embodiment, a pillar for providing at least one of the channel layer, the tunneling insulating film, the charge storage film, and the blocking insulating film may be provided in each cell string.

The source select transistor SST of each cell string is connected between a common source line CSL and the memory cells MC1 to MCp.

As an embodiment, the source select transistors of the cell strings arranged in the same row are connected to a source select line extending in the row direction, and the source select transistors of the cell strings arranged in different rows are connected to different source select lines. In FIG. 3, the source select transistors of the cell strings CS11 to CS1m of a first row are connected to a first source select line SSL1. The source select transistors of the cell strings CS21 to CS2m of a second row are connected to a second source select line SSL2.

As another embodiment, the source select transistors of the cell strings CS11 to CS1m and CS21 to CS2m may be commonly connected to one source select line.

The first to n-th memory cells MC1 to MCn of each cell string are connected between the source select transistor SST and the drain select transistor DST.

The first to n-th memory cells MC1 to MCn may be divided into first to p-th memory cells MC1 to MCp and (p+1)-th to n-th memory cells MCp+1 to MCn. The first to p-th memory cells MC1 to MCp are sequentially arranged in a direction opposite to the +Z direction, and are connected in series between the source select transistor SST and the pipe transistor PT. The (p+1)-th to n-th memory cells MCp+1 to MCn are sequentially arranged in the +Z direction, and are connected in series between the pipe transistor PT and the drain select transistor DST. The first to p-th memory cells MC1 to MCp and the (p+1)-th to n-th memory cells MCp+1 to MCn are connected to each other through the pipe transistor PT. Gates of the first to n-th memory cells MC1 to MCn of each cell string are connected to the first to n-th word lines WL1 to WLn, respectively.

A gate of the pipe transistor PT of each cell string is connected to a pipeline PL.

The drain select transistor DST of each cell string is connected between a corresponding bit line and the memory cells MCp+1 to MCn. The drain select transistor DST of cell strings arranged in the row direction is connected to the drain select line extending in the row direction. The drain select transistors of the cell strings CS11 to CS1m of the first row are connected to a first drain select line DSL1. The drain select transistors of the cell strings CS21 to CS2m of the second row are connected to a second drain select line DSL2.

The cell strings arranged in the column direction are connected to the bit lines extending in the column direction. In FIG. 3, the cell strings CS11 and CS21 of the first column are connected to the first bit line BL1. The cell strings CS1m and CS2m of the m-th column are connected to the m-th bit line BLm.

The memory cells connected to the same word line in the cell strings arranged in the row direction configure one page. For example, the memory cells connected to the first word line WL1, among the cell strings CS11 to CS1m of the first row configure one page. The memory cells connected to the first word line WL1, among the cell strings CS21 to CS2m of the second row configure another page. The cell strings arranged in one row direction may be selected by selecting any one of the drain select lines DSL1 and DSL2. One page of the selected cell strings may be selected by selecting any one of the word lines WL1 to WLn.

As another embodiment, even bit lines and odd bit lines may be provided instead of the first to m-th bit lines BL1 to BLm. In addition, even-numbered cell strings among the cell strings CS11 to CS1m or CS21 to CS2m arranged in the row direction may be connected to even bit lines, and odd-numbered cell strings among the cell strings CS11 to CS1m or CS21 to CS2m arranged in the row direction may be connected to odd bit lines, respectively.

As an embodiment, at least one of the first to n-th memory cells MC1 to MCn may be used as a dummy memory cell. For example, at least one dummy memory cell is provided to reduce an electric field between the source select transistor SST and the memory cells MC1 to MCp. Alternatively, at least one dummy memory cell is provided to reduce an electric field between the drain select transistor DST and the memory cells MCp+1 to MCn. As more dummy memory cells are provided, reliability of an operation for the memory block BLKa is improved, however, the size of the memory block BLKa increases. As less dummy memory cells are provided, the size of the memory block BLKa may be reduced, however, the reliability of the operation for the memory block BLKa may be reduced.

In order to efficiently control at least one dummy memory cell, each of the dummy memory cells may have a required threshold voltage. Before or after an erase operation for the memory block BLKa, program operations for all or some of the dummy memory cells may be performed. When the erase operation is performed after the program operation is performed, the dummy memory cells may have the required threshold voltage by controlling a voltage applied to dummy word lines connected to the respective dummy memory cells.

FIG. 4 is a circuit diagram illustrating another embodiment of any one memory block BLKb of the memory blocks BLK1 to BLKz of FIG. 2.

Referring to FIG. 4, the memory block BLKb includes a plurality of cell strings CS11′ to CS1m′ and CS21′ to CS2m′. Each of the plurality of cell strings CS11′ to CS1m′ and CS21′ to CS2m′ extends along a +Z direction. Each of the plurality of cell strings CS11′ to CS1m′ and CS21′ to CS2m′ includes at least one source select transistor SST, first to n-th memory cells MC1 to MCn, and at least one drain select transistor DST stacked on a substrate (not shown) under the memory block BLKb.

The source select transistor SST of each cell string is connected between a common source line CSL and memory cells MC1 to MCn. The source select transistors of the cell strings arranged in the same row are connected to the same source select line. The source select transistors of the cell strings CS11′ to CS1m′ arranged in a first row are connected to a first source select line SSL1. The source select transistors of the cell strings CS21′ to CS2m′ arranged in a second row are connected to a second source select line SSL2. As another embodiment, the source select transistors of the cell strings CS11′ to CS1m′ and CS21′ to CS2m′ may be commonly connected to one source select line.

The first to n-th memory cells MC1 to MCn of each cell string are connected in series between the source select transistor SST and the drain select transistor DST. Gates of the first to n-th memory cells MC1 to MCn are connected to first to the n-th word lines WL1 to WLn, respectively.

The drain select transistor DST of each cell string is connected between a corresponding bit line and the memory cells MC1 to MCn. The drain select transistors of the cell strings arranged in the row direction are connected to a drain select line extending in the row direction. The drain select transistors of the cell strings CS11′ to CS1m′ of a first row are connected to a first drain select line DSL1. The drain select transistors of the cell strings CS21′ to CS2m′ of a second row are connected to a second drain select line DSL2.

As a result, the memory block BLKb of FIG. 4 has a circuit similar to that of the memory block BLKa of FIG. 3 except that the pipe transistor PT is excluded from each cell string.

As another embodiment, even bit lines and odd bit lines may be provided instead of the first to m-th bit lines BL1 to BLm. In addition, even-numbered cell strings among the cell strings CS11′ to CS1m′ or CS21′ to CS2m′ arranged in the row direction may be connected to even bit lines, and odd-numbered cell strings among the cell strings CS11′ to CS1m′ or CS21′ to CS2m′ arranged in the row direction may be connected to odd bit lines, respectively.

As an embodiment, at least one of the first to n-th memory cells MC1 to MCn may be used as a dummy memory cell. For example, at least one dummy memory cell is provided to reduce an electric field between the source select transistor SST and the memory cells MC1 to MCn. Alternatively, at least one dummy memory cell is provided to reduce an electric field between the drain select transistor DST and the memory cells MC1 to MCn. As more dummy memory cells are provided, reliability of an operation for the memory block BLKb is improved, however, the size of the memory block BLKb increases. As less dummy memory cells are provided, the size of the memory block BLKb may be reduced, however, the reliability of the operation for the memory block BLKb may be reduced.

In order to efficiently control at least one dummy memory cell, each of the dummy memory cells may have a required threshold voltage. Before or after an erase operation for the memory block BLKb, program operations for all or some of the dummy memory cells may be performed. When the erase operation is performed after the program operation is performed, the dummy memory cells may have the required threshold voltage by controlling a voltage applied to the dummy word lines connected to the respective dummy memory cells.

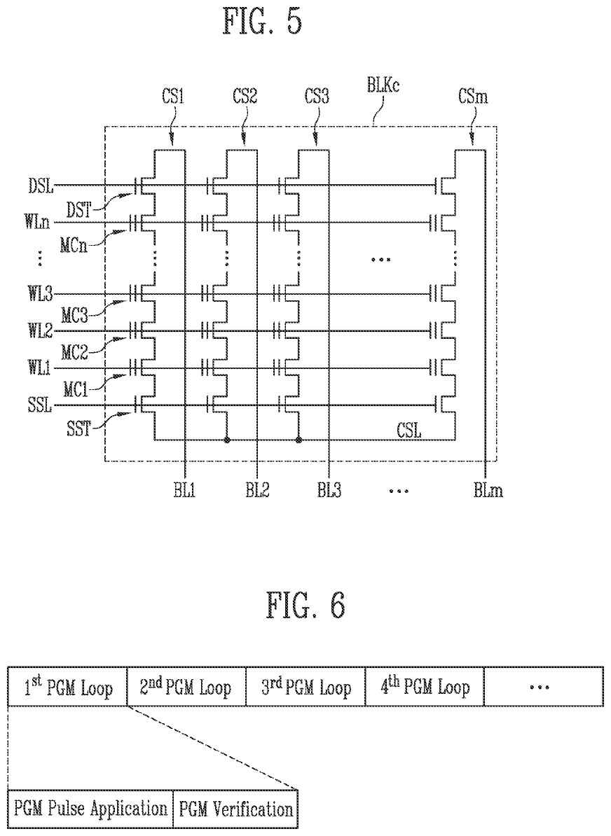

FIG. 5 is a circuit diagram illustrating an embodiment of any one memory block BLKc of the memory blocks BLK1 to BLKz included in the memory cell array 110 of FIG. 1.

Referring to FIG. 5, the memory block BLKc includes a plurality of cell strings CS1 to CSm. The plurality of cell strings CS1 to CSm may be connected to a plurality of bit lines BL1 to BLm, respectively. Each of the cell strings CS1 to CSm includes at least one source select transistor SST, first to n-th memory cells MC1 to MCn, and at least one drain select transistor DST.

Each of the select transistors SST and DST and the memory cells MC1 to MCn may have a similar structure. As an embodiment, each of the select transistors SST and DST and the memory cells MC1 to MCn may include a channel layer, a tunneling insulating film, a charge storage film, and a blocking insulating film. As an embodiment, a pillar for providing the channel layer may be provided in each cell string. As an embodiment, a pillar for providing at least one of the channel layer, the tunneling insulating film, the charge storage film, and the blocking insulating film may be provided in each cell string.

The source select transistor SST of each cell string is connected between a common source line CSL and the memory cells MC1 to MCn.

The first to n-th memory cells MC1 to MCn of each cell string are connected between the source select transistor SST and the drain select transistor DST.

The drain select transistor DST of each cell string is connected between a corresponding bit line and the memory cells MC1 to MCn.

Memory cells connected to the same word line configure one page. The cell strings CS1 to CSm may be selected by selecting the drain select line DSL. One page among the selected cell strings may be selected by selecting any one of the word lines WL1 to WLn.

As another embodiment, even bit lines and odd bit lines may be provided instead of the first to m-th bit lines BL1 to BLm. Even-numbered cell strings among the cell strings CS1 to CSm may be connected to even bit lines, and odd-numbered cell strings may be connected to odd bit lines, respectively.

As shown in FIGS. 2 to 4, the memory cell array 110 of the semiconductor memory device 100 may be configured as a memory cell array of a three-dimensional structure. In addition, as shown in FIG. 5, the memory cell array 110 of the semiconductor memory device 100 may be configured as a memory cell array of a two-dimensional structure.

FIG. 6 is a diagram illustrating a plurality of program loops included in a program operation of the semiconductor memory device 100.

Referring to FIG. 6, the program operation of the semiconductor memory device 100 may include a plurality of program loops. As shown in FIG. 6, first, a first program loop 1^{st} PGM Loop may be performed. After the first program loop 1^{st} PGM Loop is performed, when a program for the memory cells included in the selected page is not completed, a second program loop 2^{nd} PGM Loop may be performed. After the second program loop 2^{nd} PGM Loop is performed, when the program for the memory cells included in the selected page is not complete, a third program loop 3^{rd} PGM Loop may be performed. In such a method, the plurality of program loops may be repeatedly performed until the program for the memory cells included in the selected page is completed, or until a maximum program loop is reached.

Meanwhile, the program operation of the semiconductor memory device 100 may be performed using an incremental step pulse programming (ISPP) method. The ISPP method is a method of programming the memory cells while gradually increasing a program voltage. Whenever the number of times the program loop is performed is repeated, the program voltage applied in each program loop may gradually increase.

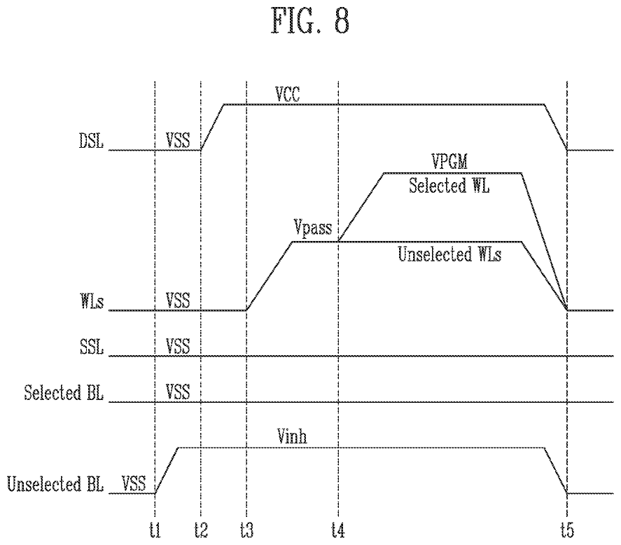

Meanwhile, as shown in FIG. 6 for the 1^{st} PGM Loop, each of the plurality of program loops may include a program pulse application step and a program verification step. In the program pulse application step, the program voltage may be applied to the selected word line to increase a threshold voltage of the program permission cells. The program pulse application step is described in detail with reference to FIG. 8.

In the program verification step, it may be verified whether memory cells selected as a program target are programmed to a voltage of a desired level (hereinafter, referred to as a “reference voltage”) or higher. As a result of the verify operation, a memory cell that is not programmed to the reference voltage or higher may operate as the program permission cell in a next program loop. At this time, a program pulse having a voltage level higher than that of a previous program loop may be applied to the program permission cells. On the other hand, a memory cell programmed to the reference voltage or higher may operate as a program inhibition cell in the next program loop. Even though the program pulse is applied to the selected word line, a threshold voltage of the program inhibited cell may not increase.

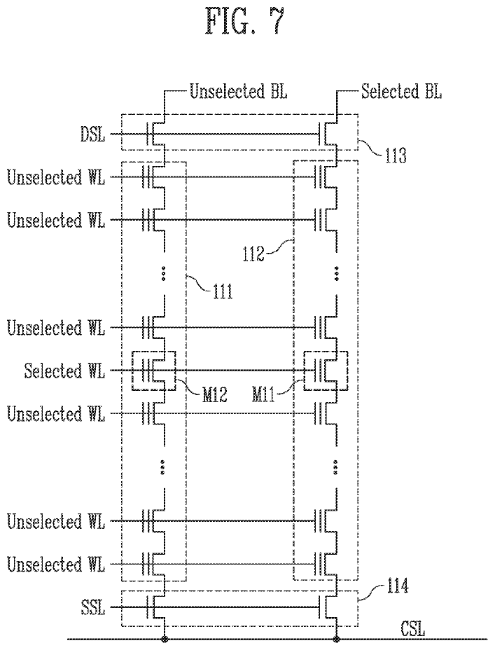

FIG. 7 is a circuit diagram illustrating the program operation of the selected memory block. In FIG. 7, only some of cell strings 111 and 112 among the plurality of cell strings included in the selected memory block are shown. In an example of FIG. 7, the cell string 111 includes a program inhibition cell M12, and the cell string 112 includes a program permission cell M11. The semiconductor memory device 100 may include the plurality of memory blocks. Among the plurality of memory blocks, the memory block that becomes the program target includes the cell strings 111 and 112 in which a plurality of memory cells for storing data are connected in series, a drain select transistor 113 connected between the cell strings 111 and 112 and the bit lines, and a source select transistor 114 connected between the cell strings 111 and 112 and a common source line CSL. Here, the cell strings 111 and 112 are configured to be as many as the number of bit lines, and thus the drain select transistor 113 and the source select transistor 114 are configured to be as many as the number of bit lines. In addition, for a predetermined operation of the memory cells, a predetermined bias is applied to a memory cell gate through a word line WL, and a predetermined bias is applied to a drain of the drain select transistor 113 through the bit lines BL, and a predetermined bias is applied to a source of the source select transistor 114 through the common source line CSL.

With respect to each of the memory cells included in the semiconductor memory device 100 according to an embodiment of the present disclosure, the program or erasure is performed by injecting or releasing an electron through Fowler-Nordheim (FN) tunneling to a floating gate of the memory cell, the erasure is performed in a block unit, and the program is performed on the selected cell.

The selected pages of the semiconductor memory device 100 may include the plurality of memory cells. Among the plurality of memory cells included in the selected page, the program permission cell may mean memory cells for which a threshold voltage is not yet increased to a target voltage. When the program voltage is applied to the selected word line, the threshold voltage of the program permission cells may increase. Meanwhile, among the plurality of memory cells included in the selected page, the program inhibition cell may mean memory cells for which a threshold voltage is increased to a target voltage. When the program voltage is applied to the selected word line, the threshold voltages of the program inhibition cells may not increase.

In the example of FIG. 7, the memory cell M11 is the program permission cell and the memory cell M12 is the program inhibition cell. In order to program the program permission cell M11 included in the selected page, a program voltage of about 18V may be applied to a selected word line Selected WL, a pass voltage of about 8V may be applied to unselected word lines, a ground voltage Vss may be applied to a selected bit line Selected BL, and a power voltage Vcc may be applied to an unselected bit line Unselected BL. At this time, the power voltage Vcc may be applied to a drain select line DSL, the ground voltage Vss may be applied to a source select line SSL, and the power voltage Vcc may be applied to the common source line CSL.

FIG. 8 is a timing diagram illustrating an embodiment of the program pulse application step shown in FIG. 6.

Referring to FIG. 8, at a time t1, a program permission voltage, for example, the ground voltage VSS, may be applied to the selected bit line Selected BL connected to a selected string including the program permission cell, and a program inhibition voltage Vinh may be applied to the unselected bit line Unselected BL connected to an unselected string including the program inhibition cell. Here, the program inhibition voltage Vinh may be a voltage greater than the program permission voltage, that is, the ground voltage VSS.

In the embodiment of FIG. 8, the program inhibition voltage Vinh is applied to the unselected bit line. However, an unselected bit line may be floated differently from that shown in FIG. 8.

At a time t2, the power voltage VCC may be applied to the drain select line DSL. Accordingly, each of the cell strings included in the selected memory block may be electrically connected to corresponding bit lines. Meanwhile, the ground voltage VSS may be applied to the source select line SSL.

At a time t3, a pass voltage Vpass is applied to word lines WLs. Meanwhile, at a time t4, a voltage of the selected word line Selected WL among the word lines WLs increases from the pass voltage Vpass to a program voltage VPGM. At this time, a voltage of the unselected word lines Unselected WLs maintains the pass voltage Vpass.

Accordingly, among the memory cells connected to the selected word line Selected WL, the program permission cells connected to the selected bit line Selected BL to which the program permission voltage, that is, the ground voltage VSS, is applied are programmed. On the other than, among the memory cells connected to the selected word line Selected WL, the program inhibition cell connected to the unselected bit line Unselected BL to which the program inhibit voltage Vinh is applied is not programmed.

Thereafter, at a time t5, voltages of the drain select line DSL, the word lines WLs, and the unselected bit line Unselected BL may decrease to the ground voltage VSS. Accordingly, at a time t5, the program pulse application step may be ended.

Meanwhile, a detailed timing diagram of the program verification step shown in FIG. 6 is omitted.

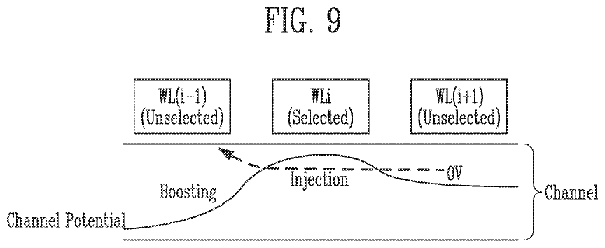

FIG. 9 is a diagram illustrating an injection phenomenon occurring during the program operation according to FIG. 8.

Referring to FIG. 9, among the word lines connected to the cell string, an i-th word line WLi, which is the selected word line, and an (i−1)-th word line WL(i−1) and an (i+1)-th word line WL(i+1) positioned adjacent thereto are shown. Meanwhile, a channel and a channel potential formed in the vicinity of the corresponding word lines are shown.

As shown in FIG. 9, when a voltage of the i-th word line WLi increases to the pass voltage or the program voltage, in a case where the memory cell connected to the i-th word line WLi is already programmed to a high threshold voltage, the memory cell connected to the i-th word line WLi temporarily maintains a turn-off state.

When the memory cell connected to the i-th word line WLi is turned off, boosting occurs in a channel region on the (i−1)-th word line WL(i−1) side. When the voltage of the i-th word line WLi continuously increases and the memory cell connected to the i-th word line WLi is weakly turned on, as shown by a dotted line of FIG. 9, an electron of an (i+1)-th word line WL(i+1) region may be injected into an (i−1)-th word line WL(i−1) region. This becomes a cause of occurring progressive disturb due to the program operation.

In accordance with a semiconductor memory device 100 and a method of operating the same according to an embodiment of the present disclosure, a time point at which a voltage of some word lines among the unselected word lines starts to increase may be delayed relative to a time point at which the voltage of the selected word line starts to increase. Accordingly, a phenomenon in which an electron is injected from the (i+1)-th word line WL(i+1) region to the (i−1)-th word line WL(i−1) region may be prevented.

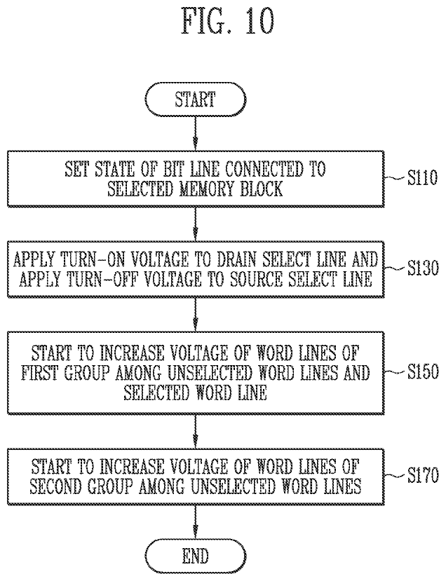

FIG. 10 is a flowchart illustrating a method of operating a semiconductor memory device, such as the semiconductor memory device 100, according to an embodiment of the present disclosure.

Referring to FIG. 10, the method of operating the semiconductor memory device 100 includes setting a state of the bit line connected to the selected memory block (S110), applying the turn-on voltage to the drain select line, and applying the turn-off voltage to the source select line (S130), starting to increase the voltage of the word lines of a first group among the unselected word lines and the selected word line (S150), and increasing the voltage of the word lines of a second group among the unselected word lines (S170).

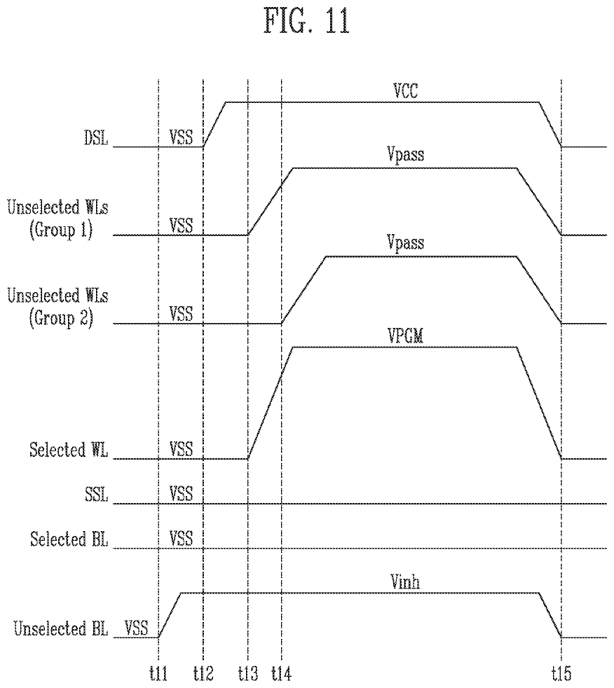

As shown in FIG. 10, among the unselected word lines, the voltage of the word lines of the first group may increase together with the selected word line (S150). Meanwhile, after the voltage of the selected word line starts to increase, the voltage of the word lines of the second group among the unselected word lines may start to increase. Accordingly, at a moment when the memory cell connected to the selected word line is weakly turned on, a phenomenon in which an electron is injected from the (i+1)-th word line WL(i+1) region adjacent to the selected word line WLi to the (i−1)-th word line WL(i−1) region may be prevented. The method of operating the semiconductor memory device 100 shown in FIG. 10 is described in detail with reference to FIG. 11 together.

FIG. 11 is a timing diagram illustrating the program pulse application step of FIG. 6 according to an embodiment of the present disclosure.

Referring to FIG. 11, at a time t11, the state of the bit line connected to the selected memory block is set (S110). More specifically, at the time t11, the program permission voltage, for example, the ground voltage VSS, may be applied to the selected bit line Selected BL connected to the selected string including the program permission cell, and the program inhibition voltage Vinh may be applied to the unselected bit line Unselected BL connected to the unselected string including the program inhibition cell. That is, step S110 of FIG. 10 may include applying the program permission voltage, for example, the ground voltage VSS, to the selected bit line Selected BL, and applying the program inhibition voltage Vinh greater than the program permission voltage to the unselected bit line.

In the embodiment of FIG. 11, the program inhibition voltage Vinh is applied to the unselected bit line in step S110. However, the unselected bit line may be floated in step S110 differently from what is shown in FIG. 11. In this case, step S110 of FIG. 10 may include applying the program permission voltage, for example, the ground voltage VSS, to the selected bit line Selected BL, and floating the unselected bit line.

At a time t12, the turn-on voltage may be applied to the drain select line DSL, and the turn-off voltage may be applied to the source select line SSL (S130). More specifically, the power voltage VCC may be applied to the drain select line DSL, and the ground voltage VSS may be applied to the source select line SSL.

At a time t13, the voltage of the word lines of the first group Group 1 among the unselected word lines starts to increase to the pass voltage (S150). Meanwhile, at the time t13, the voltage of the selected word line starts to increase to the program voltage VPGM (S150). FIG. 11 shows an embodiment in which the voltage of the selected word line increases directly from the ground voltage VSS to the program voltage VPGM, but the present disclosure is not limited thereto. For example, similarly to what is shown in FIG. 8, the voltage of the selected word line may first increase to the pass voltage Vpass together with the voltage of the unselected word line of the first group Group 1, and then increase to the program voltage VPGM again.

At a time t14, the voltage of the word lines of the second group Group 2 among the unselected word lines starts to increase to the pass voltage (S170). That is, a time point at which the voltage of the word lines of the second group Group 2 among the unselected word lines increases is later than a time point at which the voltage of the selected word line increases. Through this, the phenomenon in which an electron is injected from the (i+1)-th word line WL(i+1) region adjacent to the selected word line WLi to the (i−1)-th word line WL(i−1) region may be prevented.

The time t14 may be set after a predetermined time interval from the time t13. According to a characteristic of the memory cells, the time t14 may be determined as an appropriate time point.

As the program voltage VPGM is applied to the selected word line, among the memory cells connected to the selected word line Selected WL, the program permission cells connected to the selected bit line Selected BL to which the program permission voltage, that is, the ground voltage VSS is applied are programmed. Meanwhile, among the memory cells connected to the selected word line Selected WL, the program inhibition cell connected to the unselected bit line Unselected BL to which the program inhibition voltage Vinh is applied is not programmed.

Thereafter, at a time t15, the voltages of the drain select line DSL, the word lines WLs, and the unselected bit line Unselected BL may decrease to the ground voltage VSS. Accordingly, at the time t15, the program pulse application step may be ended.

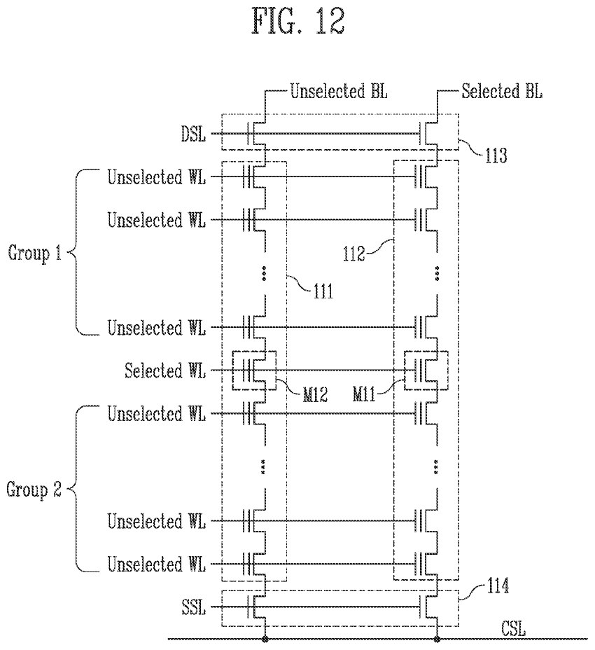

Among the unselected word lines, the word lines of the first group Group 1 for which the voltage starts to increase at the time t13 and the word lines of the second group Group 2 for which the voltage starts to increase at the time t14 may be determined by various methods. Hereinafter, embodiments in which the word line of the first group and the word line of the second group are determined among the unselected word lines are described with reference to FIGS. 12 to 15.

FIG. 12 is a circuit diagram illustrating an embodiment of the unselected word lines included in the first group and the second group.

Referring to FIG. 12, among the plurality of word lines connected to the selected memory block, the unselected word lines positioned between the drain select line DSL and the selected word line Selected WL are determined as word lines of the first group Group 1. Meanwhile, among the plurality of word lines connected to the selected memory block, the unselected word lines positioned between the source select line SSL and the selected word line Selected WL are determined as the word lines of the second group Group 2.

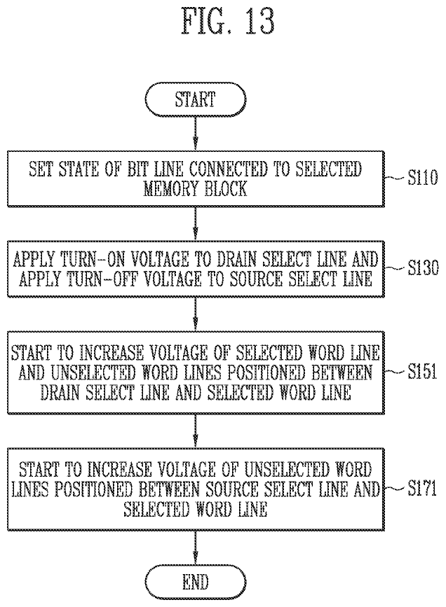

FIG. 13 is a flowchart illustrating a method of operating a semiconductor memory device, such as the semiconductor memory device 100, according to an example of FIG. 12.

Referring to FIG. 13, the method of operating the semiconductor memory device 100, according to an embodiment of the present disclosure, includes setting the state of the bit line connected to the selected memory block (S110), applying the turn-on voltage to the drain select line and applying the turn-off voltage to the source select line (S130), starting to increase the voltage of the selected word line and the unselected word lines positioned between the drain select line DSL and the selected word line Selected WL (S151), and increasing the voltage of the unselected word lines positioned between the source select line and the selected word line (S171). As described above with reference to FIG. 12, because the unselected word lines positioned between the drain select line DSL and the selected word line Selected WL are determined as the word lines of the first group Group 1, in step S151, the voltage of the word lines of the first group Group 1 and the selected word line is first started to be increased. Meanwhile, as described above with reference to FIG. 12, because the unselected word lines positioned between the source select line SSL and the selected word line Selected WL are determined as the word lines of the second group Group 2, in step S171, the voltage of the word lines of the second group Group 2 are started to be increased.

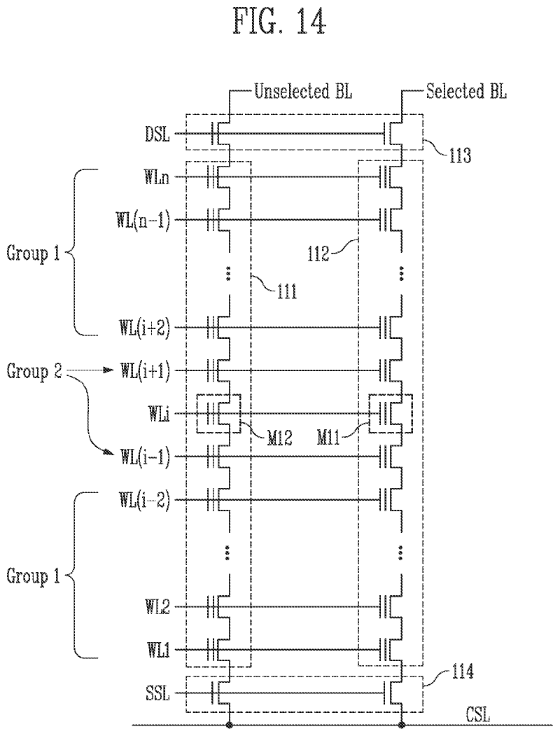

FIG. 14 is a circuit diagram illustrating another embodiment of the unselected word lines included in the first group and the second group.

Referring to FIG. 14, among the plurality of word lines connected to the selected memory block, word lines WL1 to WL(i−2) and WL(i+2) to WLn which are not adjacent to the selected word line WLi are determined as the word lines of the first group Group 1. Meanwhile, among the plurality of word lines connected to the selected memory block, the word lines WL(i−1) and WL(i+1) adjacent to the selected word line WLi are determined as the word lines of the second group Group 2.

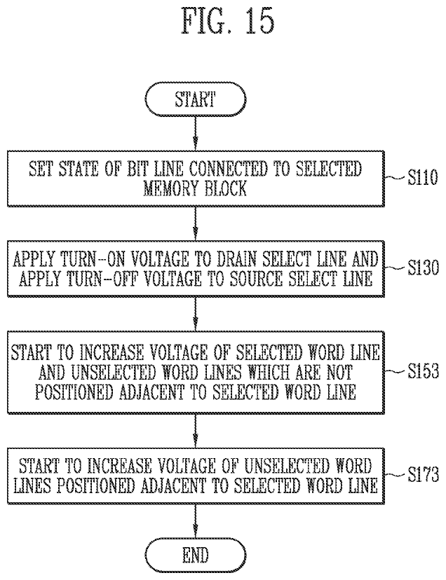

FIG. 15 is a flowchart illustrating a method of operating a semiconductor memory device, such as the semiconductor memory device 100, according to an example of FIG. 14.

Referring to FIG. 15, the method of operating the semiconductor memory device 100, according to an embodiment of the present disclosure, includes setting the state of the bit line connected to the selected memory block (S110), applying the turn-on voltage to the drain select line and applying the turn-off voltage to the source select line (S130), starting to increase a voltage of the selected word line and the unselected word lines which are not positioned adjacent to the selected word line (S153), and increasing the voltage of the unselected word lines positioned adjacent to the selected word line (S173). As described above with reference to FIG. 14, the unselected word lines WL1 to WL(i−2) and WL(i+2) to WLn which are not positioned adjacent to the selected word line are determined as the word lines of the first group Group 1, in step S153, the voltage of the word lines of the first group Group 1 and the selected word line are first started to be increased. Meanwhile, as described above with reference to FIG. 14, since the word lines WL(i−1) and WL(i+1) adjacent to the selected word line WLi are determined as the second group Group 2, in step S171, the voltage of the word lines of the second group Group 2 are started to be increased.

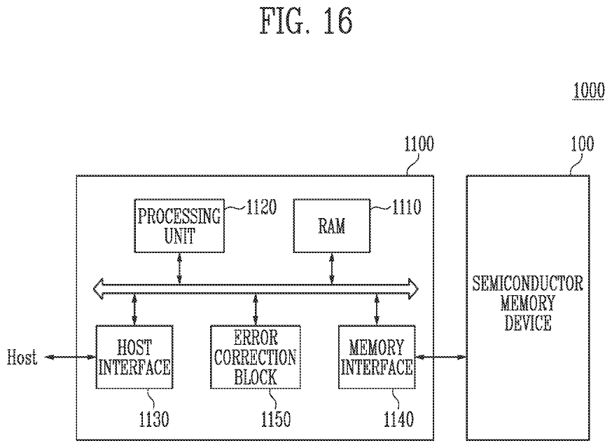

FIG. 16 is a block diagram illustrating a memory system 1000 including the semiconductor memory device 100 of FIG. 1.

Referring to FIG. 16, the memory system 1000 includes the semiconductor memory device 100 and a memory controller 1100. The semiconductor memory device 100 may be the semiconductor memory device described with reference to FIG. 1. Hereinafter, repetitive descriptions are omitted.

The memory controller 1100 is connected to a host Host and the semiconductor memory device 100. The memory controller 1100 is configured to access the semiconductor memory device 100 in response to a request from the host Host. For example, the memory controller 1100 is configured to control read, write, erase, and background operations of the semiconductor memory device 100. The memory controller 1100 is configured to provide an interface between the semiconductor memory device 100 and the host Host. The memory controller 1100 is configured to drive firmware for controlling the semiconductor memory device 100.

The memory controller 1100 includes random access memory (RAM) 1110, a processing unit 1120, a host interface 1130, a memory interface 1140, and an error correction block 1150. The RAM 1110 is used as at least one of operation memory of the processing unit 1120, cache memory between the semiconductor memory device 100 and the host Host, and buffer memory between the semiconductor memory device 100 and the host Host. The processing unit 1120 controls an overall operation of the memory controller 1100. In addition, the memory controller 1100 may temporarily store program data provided from the host Host during the write operation.

The host interface 1130 includes a protocol for performing data exchange between the host Host and the memory controller 1100. As an embodiment, the memory controller 1100 is configured to communicate with the host Host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial ATA protocol, a parallel ATA protocol, a small computer system interface (SCSI) protocol, an enhanced small disk interface (ESDI) protocol, an integrated drive electronics (IDE) protocol, and a private protocol.

The memory interface 1140 interfaces with the semiconductor memory device 100. For example, the memory interface 1240 includes a NAND interface or a NOR interface.

The error correction block 1150 is configured to detect and correct an error of data received from the semiconductor memory device 100 using an error correcting code (ECC). As an embodiment, the error correction block may be a component of the memory controller 1100.

The memory controller 1100 and the semiconductor memory device 100 may be integrated into one semiconductor device. As an embodiment, the memory controller 1100 and the semiconductor memory device 100 may be integrated into one semiconductor device to form a memory card. For example, the memory controller 1100 and the semiconductor memory device 100 may be integrated into one semiconductor device to form a memory card such as a PC card (personal computer memory card international association (PCMCIA)), a compact flash card (CF), a smart media card (SM or SMC), a memory stick, a multimedia card (MMC, RS-MMC, or MMCmicro), an SD card (SD, miniSD, microSD, or SDHC), or a universal flash storage (UFS).

The memory controller 1100 and the semiconductor memory device 100 may be integrated into one semiconductor device to form a semiconductor drive (solid state drive (SSD)). The semiconductor drive (SSD) includes a storage device configured to store data in a semiconductor memory. When the memory system 1000 is used as the semiconductor drive (SSD), an operation speed of the host connected to the memory system 1000 is improved.

As another example, the memory system 1000 is provided as one of various components of an electronic device such as a computer, an ultra-mobile PC (UMPC), a workstation, a net-book, a personal digital assistants (PDA), a portable computer, a web tablet, a wireless phone, a mobile phone, a smart phone, an e-book, a portable multimedia player (PMP), a portable game machine, a navigation device, a black box, a digital camera, a 3-dimensional television, a digital audio recorder, a digital audio player, a digital picture recorder, a digital picture player, a digital video recorder, and a digital video player, a device capable of transmitting and receiving information in a wireless environment, one of various electronic devices configuring a home network, one of various electronic devices configuring a computer network, one of various electronic devices configuring a telematics network, an RFID device, or one of various components configuring a computing system.

As an embodiment, the semiconductor memory device 100 or the memory system 1000 may be mounted as a package of various types. For example, the semiconductor memory device 1300 or the memory system 1000 may be packaged and mounted in a method such as a package on package (PoP), ball grid arrays (BGAs), chip scale packages (CSPs), plastic leaded chip carriers (PLCC), a plastic dual in line package (PDIP), a die in waffle pack, die in wafer form, a chip on board (COB), a ceramic dual in line package (CERDIP), a plastic metric quad flat pack (MQFP), a thin quad flat pack (TQFP), a small outline integrated circuit package (SOIC), a shrink small outline package (SSOP), a thin small outline package (TSOP), a system in package (SIP), a multi-chip package (MCP), a wafer-level fabricated package (WFP), or a wafer-level processed stack package (WSP).

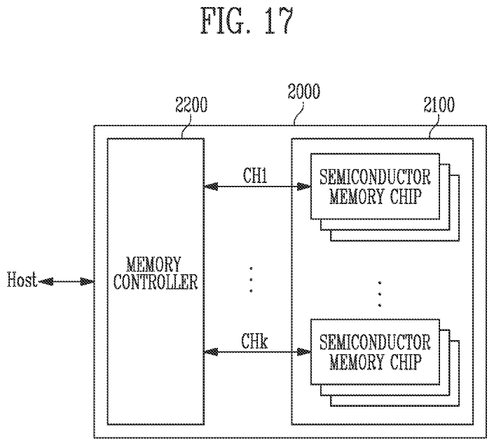

FIG. 17 is a block diagram illustrating an application example of the memory system 1000 of FIG. 16.

Referring to FIG. 17, a memory system 2000 includes a semiconductor memory device 2100 and a memory controller 2200. The semiconductor memory device 2100 includes a plurality of semiconductor memory chips. The plurality of semiconductor memory chips are divided into a plurality of groups.

In FIG. 17, the plurality of groups communicate with the memory controller 2200 through first to k-th channels CH1 to CHk, respectively. Each semiconductor memory chip is configured and is operated similarly to that of the semiconductor memory device 100 described with reference to FIG. 1.

Each group is configured to communicate with the memory controller 2200 through one common channel. The memory controller 2200 is configured similarly to the memory controller 1100 described with reference to FIG. 16 and is configured to control the plurality of memory chips of the semiconductor memory device 2100 through the plurality of channels CH1 to CHk.

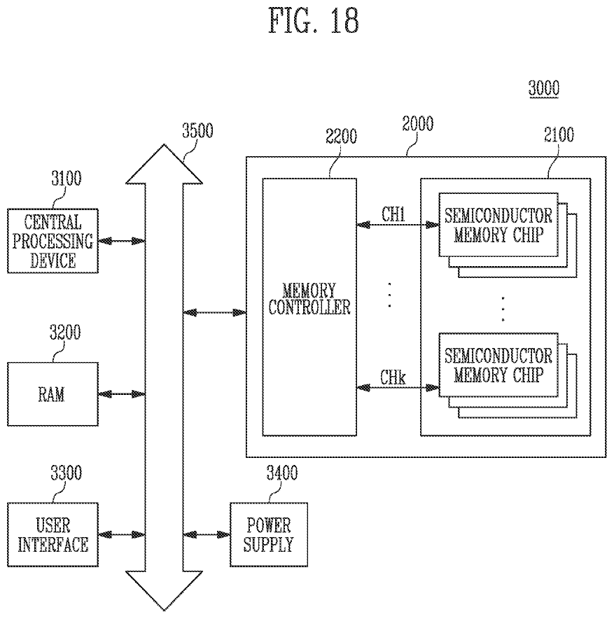

FIG. 18 is a block diagram illustrating a computing system 3000 including the memory system 2000 described with reference to FIG. 17.

The computing system 3000 includes a central processing device 3100, random access memory (RAM) 3200, a user interface 3300, a power supply 3400, a system bus 3500, and the memory system 2000.

The memory system 2000 is electrically connected to the central processing device 3100, the RAM 3200, the user interface 3300, and the power supply 3400 through the system bus 3500. Data provided through the user interface 3300 or processed by the central processing device 3100 is stored in the memory system 2000.

In FIG. 18, the semiconductor memory device 2100 is connected to the system bus 3500 through the memory controller 2200. However, the semiconductor memory device 2100 may be configured to be directly connected to the system bus 3500. At this time, a function of the memory controller 2200 is performed by the central processing device 3100 and the RAM 3200.

In FIG. 18, the memory system 2000 described with reference to FIG. 17 is illustrated. However, the memory system 2000 may be replaced with the memory system 1000 described with reference to FIG. 16. As an embodiment, the computing system 3000 may be configured to include both of the memory systems 1000 and 2000 described with reference to FIGS. 16 and 17.

What is claimed is:

1. A method of operating a semiconductor memory device for programming selected memory cells among a plurality of memory cells, the method comprising:
setting a state of bit lines connected to a selected memory block including the selected memory cells;
applying a turn-on voltage to a drain select line connected to the selected memory block, and applying a turn-off voltage to a source select line connected to the memory block;
starting to increase a voltage of word lines of a first group of word lines including unselected word lines which are not connected to the selected memory cells and a selected word line connected to the selected memory cells, among a plurality of word lines connected to the selected memory block; and
starting to increase a voltage of word lines of a second group of word lines including unselected word lines connected to the selected memory block which are not in the first group of word lines.

2. The method of claim 1, wherein the first group includes unselected word lines positioned between the drain select line and the selected word line.

3. The method of claim 2, wherein the second group includes unselected word lines positioned between the source select line and the selected word line.

4. The method of claim 1, wherein the first group includes unselected word lines which are not positioned adjacent to the selected word line.

5. The method of claim 4, wherein the second group includes unselected word lines positioned adjacent to the selected word line.

6. The method of claim 1, wherein starting to increase the voltage of the word lines of the first group comprises:
starting to increase the voltage of the unselected word lines of the first group from a ground voltage to a pass voltage; and
starting to increase the voltage of the selected word line of the first group from the ground voltage to a program voltage.

7. The method of claim 6, wherein starting to increase the voltage of the word lines of the second group comprises starting to increase the voltage of the word lines of the second group from the ground voltage to the pass voltage.

8. The method of claim 1, wherein starting to increase the voltage of the word lines of the first group comprises starting to increase the voltage of the unselected word lines of the first group and the voltage of the selected word line of the first group from a ground voltage to a pass voltage.

9. The method of claim 8, further comprising increasing the voltage of the selected word line from the pass voltage to the program voltage, after the voltage of the selected word line is increased to the pass voltage.

10. The method of claim 1, wherein setting the state of the bit lines comprises:
applying a program permission voltage to a selected bit line among the bit lines; and
applying a program inhibition voltage greater than the program permission voltage to an unselected bit line.

11. The method of claim 10, wherein the program permission voltage is a ground voltage.

12. The method of claim 1, wherein setting the state of the bit line comprises:
applying a program permission voltage to a selected bit line among the bit lines; and
floating an unselected bit line.

13. A semiconductor memory device comprising:
a plurality of memory blocks each including a plurality of memory cells;
a peripheral circuit configured to perform a program operation on selected memory cells of a selected memory block among the plurality of memory blocks; and
control logic capable of controlling the program operation performed by the peripheral circuit,
wherein each of the plurality of memory blocks is connected to at least one drain select line, at least one source select line, and a plurality of word lines, and
wherein the control logic is capable of:
controlling the peripheral circuit to apply a turn-on voltage to at least one drain select line connected to the selected memory block and apply a turn-off voltage to at least one source select line connected to the memory block;
controlling the peripheral circuit to increase a voltage of unselected word lines included in a first group which are not connected to the selected memory cells and a selected word line included in the first group which is connected to the selected memory cells, among a plurality of word lines connected to the selected memory block; and
controlling the peripheral circuit to increase, after the voltage of the unselected word lines of the first group and the selected word line are started to be increased, a voltage of word lines included in a second group of word lines including unselected word lines connected to the selected memory block which are not in the first group of word lines.

14. The semiconductor memory device of claim 13, wherein the first group includes unselected word lines positioned between the at least one drain select line and the selected word line.

15. The semiconductor memory device of claim 14, wherein the second group includes unselected word lines positioned between the at least one source select line and the selected word line.

16. The semiconductor memory device of claim 13, wherein the first group includes unselected word lines which are not positioned adjacent to the selected word line.

17. The semiconductor memory device of claim 16, wherein the second group includes unselected word lines positioned adjacent to the selected word line.

18. The semiconductor memory device of claim 13, wherein the control logic is capable of controlling the peripheral circuit to:
increase the voltage of the unselected word lines of the first group from a ground voltage to a pass voltage; and
increase the voltage of the selected word line of the first group from the ground voltage to a program voltage.

19. The semiconductor memory device of claim 18, wherein the control logic is capable of controlling the peripheral circuit to increase the voltage of the word lines of the second group from the ground voltage to the pass voltage.

20. The semiconductor memory device of claim 13, wherein the control logic is capable of controlling the peripheral circuit to:
increase the voltage of the unselected word lines of the first group and the selected word line of the first group from a ground voltage to a pass voltage; and
further increase the voltage of the selected word line from the pass voltage to the program voltage.
